(19) United States
(12) Patent Application Publication
(10) Pub. No.: US 2005/0156261 A1
(43) Pub. Date: Jul. 21, 2005

(54) Optical sensor and display

(75) Inventors: Ryuji Nishikawa, Gifu-city (JP); Takashi Ogawa, Anpachi-gun (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/019,647

(22) Filed: Dec. 23, 2004

(30) Foreign Application Priority Data
Dec. 24, 2003 (JP) 2003-427195
Nov. 26, 2004 (JP) 2004-342659

(51) Int. Cl. H01L 29/04

(52) U.S. Cl. 257/431

(57) ABSTRACT

Conventionally, in the case where optical sensors are included in a display device, separate modules manufactured in separate steps are included in the same casing. However, reduction in the number of parts and in costs cannot be achieved, and reduction in size and thickness of the display device has not been realized. An optical sensor is realized by use of a TFT provided on an insulating substrate. The TFT is used as the optical sensor by detecting a photocurrent generated by incident ambient light when the TFT is off. By increasing a gate width W of the TFT, a region where the photocurrent is generated is increased, and the optical sensor with good sensitivity is realized. Moreover, since the optical sensor can be realized by use of a TFT provided on a glass substrate, the optical sensor can be provided on the same substrate as that of an EL display device.

### BACKGROUND OF THE INVENTION

1. Field of the Invention

The present invention relates to an optical sensor and a display, and more particularly to an optical sensor using a thin film transistor and a display having the optical sensor and a display unit on the same substrate.

2. Description of the Related Art

As to a current display device, in response to market demands for reduction in size, weight and thickness of the display device, a flat panel display is in popular use. Most of such display devices include optical sensors, such as an optical touch panel which detects input coordinates by shutting out light, and one which controls brightness of a screen of a display by detecting ambient light, for example.

For example, FIG. 7A shows an example of the optical touch panel. In the optical touch panel 301, a light emitting device 303 which emits infrared light or the like, and a light receiving device 304 which receives the light are arranged in a periphery of a screen 302. In such an optical touch panel, by shutting out the infrared light emitted by the light emitting device 303 with a finger or the like, for inputting coordinates, points at which the infrared light does not reach the light receiving device 304 are detected as input coordinates (for example, see Japanese Patent Laid-Open No. Hei 5(1993)-35402 (Pages 2 and 3, FIG. 2)).

Moreover, FIG. 7B shows a display device which has an optical sensor 306 attached to a LCD (Liquid Crystal Display) 305 and controls backlight brightness of a display screen of the LCD according to surrounding light received. For this optical sensor, a photoelectric conversion element 306 of a CdS (Cadmium Sulfide) cell, for example, is used (for example, see Japanese Patent Laid-Open No. Hei 6(1994)-11713 (Page 3, FIG. 1)).

Regarding a conventional flat panel display, a display unit and an optical sensor are generally manufactured as separate module parts through separate manufacturing processes by use of separate manufacturing installations. These module parts are assembled in the same casing to obtain a finished product. Thus, reduction in the number of parts of the device, and reduction in manufacturing costs of the respective module parts have their limits.

Particularly, today, mobile terminals such as a portable telephone and a PDA (Personal Digital Assistance), for example, have rapidly become popular. Accordingly, further reduction in size, weight and thickness of the display device has been demanded. Specifically, as to the optical sensor used in such a display device, it has been also desired to miniaturize the optical sensor or to reduce the number of parts, and to provide the optical sensor at a low price.

### SUMMARY OF THE INVENTION

The invention provides an optical sensor that includes a substrate, and a semiconductor layer disposed over the substrate and having a source, a drain and a channel disposed between the source and the drain. The semiconductor layer is configured to generate photocurrents in response to incident light. The sensor also includes a gate electrode disposed over the substrate. The gate width of the gate electrode is at least 10 times as large as a gate length of the gate electrode. A gate insulating film is disposed between the semiconductor layer and the gate electrode.

The invention also provides a display device that includes a substrate, a display unit disposed on the substrate and having a plurality of pixels each including a thin film transistor, and an optical sensor that includes a semiconductor layer disposed over the substrate, a gate electrode disposed over the substrate and a gate insulating film disposed between the semiconductor layer and the gate electrode. The gate width of the gate electrode is at least 10 times as large as a gate length of the gate electrode, and the semiconductor layer has a source, a drain and a channel disposed between the source and the drain.

The invention further provides an optical sensor that includes a substrate, and a first thin film transistor and a second thin film transistor that are connected in parallel and configured to generate photocurrents in response to incident light. Each of the first and second thin film transistor has a semiconductor layer disposed over the substrate, a gate electrode disposed over the substrate and a gate insulating film disposed between the semiconductor layer and the gate electrode. The direction of gate length of the first thin film transistor is different from the direction of gate length of the second thin film transistor.

### BRIEF DESCRIPTION OF THE DRAWINGS

FIG. 1A is a cross-sectional view, FIG. 1B is a plan view, and FIG. 1C is a schematic view for explaining an optical sensor according to a first embodiment of the present invention.

FIGS. 2A and 2B are characteristic diagrams showing a relationship between Vg and Id of the optical sensor of the present invention.

FIG. 3A is a schematic view, and FIG. 3B is a characteristic diagram for explaining the optical sensor having an LDD structure of the present invention.

FIGS. 4A and 4B are plan views, and FIG. 4C is a cross-sectional view showing a display according to a second embodiment of the present invention.

FIG. 5A is a plan view, FIG. 5B is a cross-sectional view, and FIG. 5C is a schematic circuit diagram explaining a display according to a third embodiment of the present invention.

FIG. 6 is a characteristic diagram showing a relationship between a light source and Ioff according to the present invention.

FIG. 7A is a cross-sectional view and FIG. 7B is a plan view explaining a conventional technology.

### DETAILED DESCRIPTION OF THE PREFERRED EMBODIMENTS

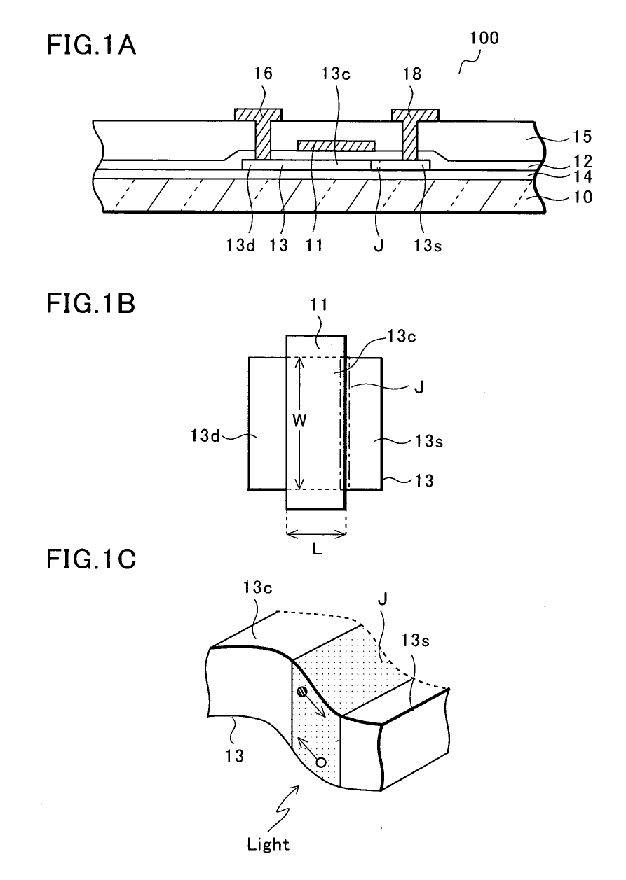

With reference to FIGS. 1A to 6, embodiments. of the present invention will be described in detail. First, FIGS. 1A to 3B show a first embodiment.

An optical sensor according to the first embodiment is a thin film transistor (hereinafter referred to as a TFT) which includes a gate electrode, an insulating film, and a semiconductor layer.

As shown in FIG. 1A, an insulating film (SiN, SiO₂, or the like) 14 to be a buffer layer is provided on an insulating substrate 10 made of quartz glass, non-alkali glass, or the like. On the insulating film 14, a semiconductor layer 13 made of a poly-silicon (hereinafter referred to as “p-Si”) film is laminated. On the semiconductor layer 13, a gate insulating film 12 made of SiN, SiO₂, or the like is laminated. On the gate insulating film 12, a gate electrode 11 made of refractory metal such as chrome (Cr) and molybdenum (Mo) is formed.

In the semiconductor layer 13, an intrinsic or substantially intrinsic channel 13c is provided, which is positioned below the gate electrode 11. Moreover, on both sides of the channel 13c, a source 13s and a drain 13d are provided, which are diffusion regions of n+impurities.

On the entire surfaces of the gate insulating film 12 and the gate electrode 11, an interlayer insulating film 15 is provided by laminating a SiO₂ film, a SiN film and a SiO₂ film, for example, in this order. In the gate insulating film 12 and the interlayer insulating film 15, contact holes are provided so as to correspond to the drain 13d and the source 13s. The contact holes are filled with metal such as aluminum (Al) to provide a drain electrode 16 and a source electrode 18. The respective electrodes are allowed to come into contact with the drain 13d and the source 13s. A photocurrent amplified by an optical sensor 100 is outputted, for example, from the source electrode 18 side.

FIG. 1B shows a plan view of the TFT (the semiconductor layer 13 and the gate electrode 11) to be the optical sensor 100. The gate electrode 11 of the TFT is disposed so as to be orthogonal to the semiconductor layer 13. In this event, gate width W of the gate electrode 11 is set to be significantly longer than gate length L of the gate electrode 11. The TFT can be operated as the optical sensor 100 if the gate length L is 0.5 μm or more and the gate width W is 5 μm or more. Specifically, it is preferable that the gate length L is about 5 μm to 15 μm, and the gate width W is about 5 to 10000 μm. Note that, as shown in FIG. 1B, the gate width W is a width of a portion where the gate electrode 11 and the semiconductor layer 13 overlap each other. It is preferable that the gate width W is not less than 10 times long as the gate length L.

FIG. 1C is a schematic view showing, in three dimensions, an energy band near a junction region between the channel 13c and the source 13s (or the drain 13d) in the semiconductor layer 13.

In the p-Si TFT having the foregoing structure, if light enters the semiconductor layer 13 from the outside when the TFT is off, a junction region J arises in the vicinity of a boundary between the channel 13c and the source 13s or between the channel 13c and the drain 13d. The junction region J is a region in the vicinity of the boundary between the channel 13c and the source 13s (or the drain 13d) adjacent thereto, as indicated by broken lines in FIGS. 1A and 1B. In the vicinity of a junction surface between the substantially intrinsic channel 13c and the source 13s having a predetermined impurity concentration, a region in which transition of the energy band takes place arises from a difference in the impurity concentration between the channel and the source, as shown in FIG. 1C. Moreover, it is conceivable that the impurity concentration around the junction surface (boundary) has an intermediate value between those of the channel 13c and the source 13s. In this embodiment, such a region in the vicinity of the boundary is called the junction region J.

In the junction region J, electron-hole pairs are separated by the electric field in the junction region J to generate photoelectromotive force. Thus, a photocurrent is obtained. In this embodiment, an increase in such photocurrents is used as the optical sensor. This photocurrent obtained when the TFT is off will be hereinafter referred to as Ioff. If Ioff is large, good sensitivity as the optical sensor is obtained.

The electron-hole pairs are generated by the incident light in the junction region J between the source 13s and the channel 13c, which is indicated by hatching in FIG. 1C. Specifically, if a large junction region J is secured, larger Ioff can be obtained. In this embodiment, a large area of the junction region J is secured by increasing the gate width W directly contributing to the junction region. Thus, the optical sensor with good sensitivity is realized.

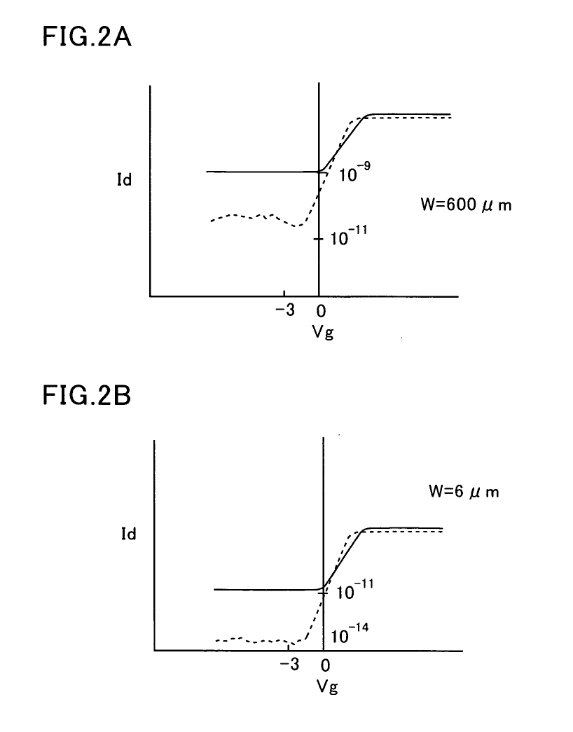

FIGS. 2A and 2B show Vg-Id curves of the TFT to be the optical sensor 100. FIG. 2A shows the curve when the gate width W is 600 μm, and FIG. 2B shows the curve when the gate width W is 6 μm. Moreover, in both of FIGS. 2A and 2B, the gate length L is 13 μm. Each of the graphs shows a case with incident light (the solid line) and a case without incident light (the broken line) under conditions of a drain voltage Vd=10V and a source voltage Vs=GND by use of an n-channel type TFT as an example.

In FIGS. 2A and 2B, the TFT is set in an off state when the gate voltage Vg is 0V to −1V or less, and, when the gate voltage Vg exceeds a threshold, the TFT is set in an on state, and a drain current Id is increased. For example, attention is focused around the gate voltage Vg=−3V at which the TFT is completely in the off state. In the case of FIG. 2A, Ioff of around 1×10⁻¹¹A in the case without incident light is increased by incident light to about 1×10⁻⁹A.

Meanwhile, as shown in FIG. 2B, if the gate width W is small, a photocurrent of 1×10⁻¹⁴A in the case without incident light is increased by incident light to 1×10⁻¹¹A. In the case of FIG. 2B, although the increased current can be detected as Ioff, the increase is of an extremely small order. Thus, it becomes difficult to feedback the increased current as Ioff. Consequently, the TFT may not function as the optical sensor. Therefore, it is preferable that the TFT is designed so as to set Ioff to 1×10⁻⁹A or more.

As described above, by increasing the gate width W, if the amount of light is the same, larger Ioff can be obtained compared to the case where the gate width W is small. Moreover, large Ioff can be obtained even by a minute amount of ambient light.

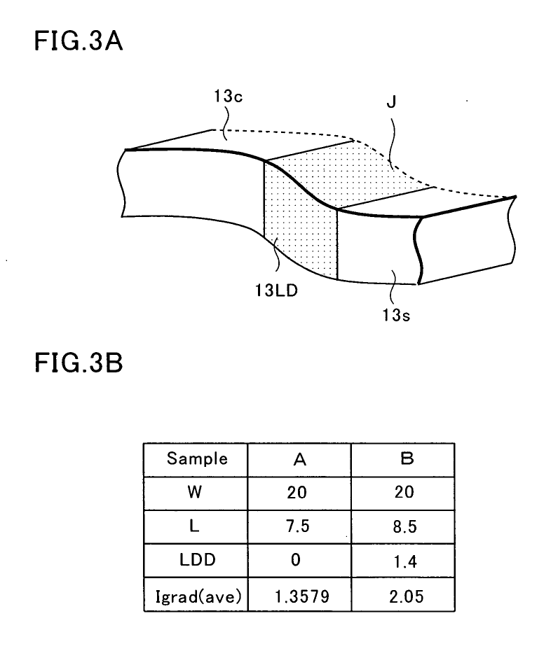

Moreover, in the semiconductor layer 13, a low concentration impurity region may be provided on a side where the photocurrent is taken. FIG. 3A is a schematic view showing the energy band in three dimensions.

The low concentration impurity region is a region which is provided between the channel 13c and the source 13s or between the channel 13C and the drain 13d and has a lower impurity concentration than that of the source 13s or the drain 13d. By providing this low concentration impurity region, it is possible to reduce the electric field concentrating on an end of the source 13s (or the drain 13d). However, the electric field is increased if the impurity concentration gets too low. Moreover, width of the low concentration impurity region (a length from the end of the source 13s to the direction of the channel 13c) also affects electric field intensity. Specifically, the impurity concentration of the low concentration impurity region and the width thereof have optimum values of, for example, about 0.5 μm to 3 μm for the width thereof.

In this embodiment, a low concentration impurity region 13LD is provided between the channel and the source (or between the channel and the drain), for example. Thus, a so-called LDD (light doped drain) structure is obtained.

When the LDD structure is adopted, the region having the intermediate impurity concentration between the channel 13c and the source 13s is expanded. Specifically, this means that the junction region J indicated by hatching is expanded toward the source 13s side, and the slope of the energy band becomes gentle.

If the gate width W is the same, when the slope is gentler, the junction region J contributing to occurrence of the photocurrent can be more increased in the direction of the gate length L. Specifically, the number of atoms of impurities in the junction region J can be increased, and the photocurrent becomes likely to occur.

FIG. 3B shows two cases which are compared in terms of the presence and absence of the LDD structure. FIG. 3B shows Igrad values indicating proportions of changes in the drain current Id to the incident light, which are measured for Sample A having no LDD structure provided therein and Sample B having the LDD structure with the width of 1.4 μm. Note that Igrad (ave) in FIG. 3B is an average of respective Igrad values of white, red, blue and green light sources. Here, although Sample A and Sample B have the same gate width (W), gate lengths (L) thereof are different. However, if the gate length is not less than 5 μm, there is almost no difference in Ioff due to the difference in the gate length L. Thus, there is no influence on the comparison.

According to the table of FIG. 3B, in Sample A having no LDD structure, Igrad (ave) is 1.3579. Meanwhile, in Sample B having the LDD structure, Igrad (ave) is 2.05. Accordingly, it is found out that larger Ioff can be obtained with a small amount of light if the LDD structure is adopted. Moreover, as indicated by the broken lines in FIGS. 2A and 2B, for example, if no LDD structure is adopted, Vg-Id characteristics are unstable when the TFT is off. However, by adopting the LDD structure, the characteristics are stabilized, in other words, leak characteristics are stabilized. Accordingly, there can have a margin in setting each voltage. Thus, the TFT can be easily used as the optical sensor.

Since the above-described optical sensor is the TFT, the TFT can be turned on by applying a predetermined voltage to the gate electrode 11. Specifically, the optical sensor can be refreshed by applying within a predetermined time, to the gate electrode, drain and/or source of the optical sensor, such a voltage as to allow a current to flow in a direction opposite to a direction of the flow of the photocurrent. Accordingly, characteristics of the TFT as the optical sensor can be stabilized. However, in the case of a diode, not the TFT, since the gate electrode and the source (or the drain) are connected to each other, the gate electrode and the source always have the same potential. Accordingly, the voltage cannot be applied to the gate electrode and the source independently from each other. Thus, the optical sensor cannot be refreshed. Furthermore, in the case of a p-n junction diode, leak characteristics are unstable when there is no incident light. Thus, the p-n junction diode is unsuitable for the optical sensor.

Although a so-called top gate TFT has been described above, the same goes for a bottom gate TFT in which the order of laminating the gate electrode, the gate insulating film and the semiconductor layer is reversed.

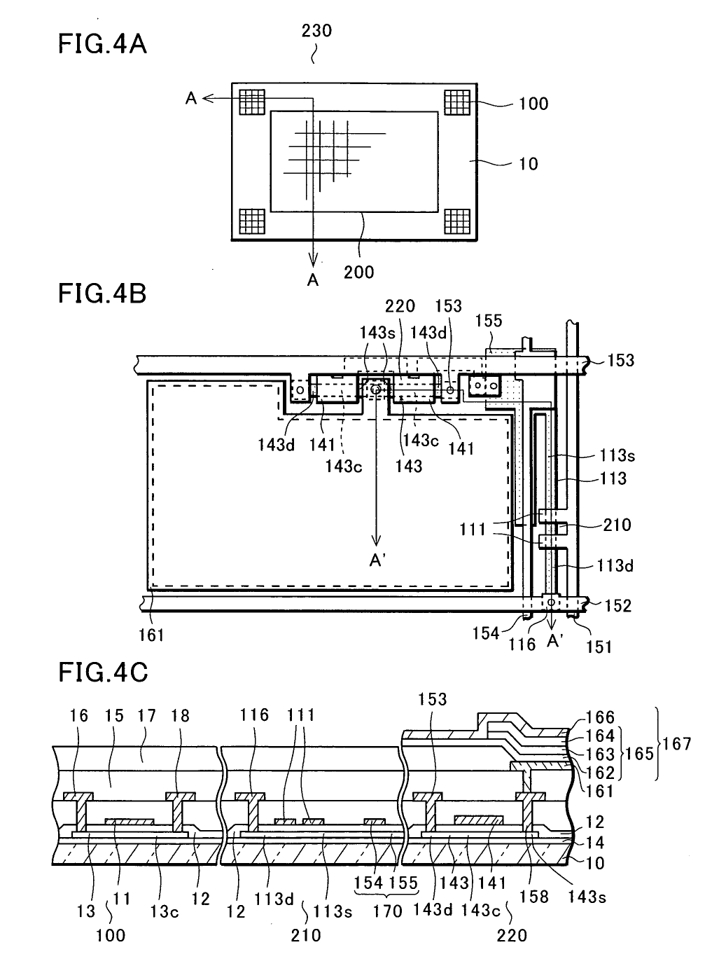

Next, with reference to FIGS. 4A to 4C, a second embodiment will be described. The second embodiment is a display 230 in which a display unit and optical sensors are arranged on the same substrate.

FIG. 4A shows a plan view of the display 230. In the display unit 200, a plurality of pixels formed of organic EL elements and thin film transistors are arranged in a matrix manner. Around the display unit 200 (for example, in four corners thereof), the optical sensors 100 are arranged. The optical sensors 100, which are the same optical sensors in the first embodiment, receive surrounding light and control brightness of the display unit 200.

A plurality of optical sensors 100 may be arranged in the respective corners. By providing a plurality of TFTs (the optical sensors 100), redundancy as optical sensor, and averaging of light received can be achieved. If the plurality of the optical sensors 100 are arranged as described above, the respective sensors may be connected in parallel to have a total gate width W of about 100 μm. Moreover, a region in which sensors can be arranged around the display unit is limited. Thus, patterns of the gate width W may be contrived so as to meander.

Since the optical sensors 100 and the display unit 200 are provided on the same insulating substrate 10, the optical sensors 100 can sense the same amount of light as that of the display unit 200. The optical sensors 100 sense an amount of light incident on the display unit 200, convert the light into currents, and control a controller, for example, which controls the brightness of the display unit 200. According to an amount of currents from the optical sensors 100, the controller sets the display unit 200 to be bright when it is bright in a room or in the open air, and sets brightness accordingly in dark surroundings. Specifically, the brightness is increased in bright surroundings, and the brightness is reduced when it is dark. By automatically controlling the brightness according to the amount of surrounding light as described above, it is possible to save power while improving visibility. Therefore, in a display using self-luminous elements such as organic EL elements, for example, life of the luminous elements can be extended.

FIG. 4B is a plan view showing a display pixel of the display unit shown in FIG. 4A. FIG. 4C shows a cross-sectional view taken along the line A-A in FIG. 4A (along the line A′-A′ in FIG. 4B, for a pixel portion). Note that, for simplification, a cross-sectional view of only one sensor is shown for an optical sensor portion.

As shown in FIG. 4B, a pixel is formed in a region surrounded by a gate signal line 151 and a drain signal line 152. A first TFT 210 that is a switching element is provided near the intersection of the both signal lines. A source 113s of the first TFT 210 also serves as a capacitance electrode 155 which forms a capacitance 170 together with a hold capacitance electrode 154 to be described later. In addition, the source 113s is connected to a gate 141 of a second TFT 220 which drives an organic EL element 167. A source 143s of the second TFT 220 is connected to an anode 161 of the organic EL element 167, and a drain 143d thereof is connected to a drive power line 153 which drives the organic EL element 167.

Moreover, near a TFT, the hold capacitance electrode 154 is arranged in parallel with the gate signal line 151. The hold capacitance electrode 154 is made of chrome or the like, and stores charges with the capacitance electrode 155 connected to the source 113s of the first TFT 210 through a gate insulating film 12 to form the capacitance. This hold capacitance 170 is provided to hold a voltage applied to the gate 141 of the second TFT 220.

With reference to FIG. 4C, description will be given of the first TFT 210 that is a TFT for switching, the second TFT 220 that is a TFT for driving the organic EL elements 167, and the optical sensor 100.

Note that structures of the first and second TFTs 210 and 220 are approximately the same as that of the TFT of the first embodiment shown in FIG. 1A. Thus, detailed description of repetitive portions will be omitted.

In the first TFT 210, an insulating film 14 to be a buffer layer is provided on an insulating substrate 10 made of quartz glass, non-alkali glass, or the like. On the insulating film 14, a semiconductor layer 113 made of a p-Si film is formed. In the semiconductor layer 113, an intrinsic or substantially intrinsic channel 113c is provided. On both sides of the channel 113c, a low concentration impurity region 113LD is provided. Further on the outside thereof, n-type source 113s and drain 113d of high concentration impurity regions are provided. Accordingly, a so-called LDD structure is formed.

On the semiconductor layer 113, the gate insulating film 12 is provided. On the gate insulating film 12, a gate signal line 151, which also serves as a gate electrode 111 made of refractory metal, and a hold capacitance electrode line 154 are provided.

On the entire surfaces of the gate insulating film 12, the gate electrode 111, the gate signal line 151, and the hold capacitance electrode line 154, an interlayer insulating film 15 is laminated. A contact hole provided in the gate insulating film 12 and the interlayer insulating film 15 so as to correspond to the drain 113d is filled with metal. Thus, a drain electrode 116 is provided, which also serves as the drain signal line 152. Note that the source 113s is extended to form the hold capacitance 170.

Furthermore, a planarizing insulating film 17 which is made of organic resin, for example, and planatizes the surface is provided on the entire surface.

In the second TFT 220, a semiconductor layer 143 is provided on the same insulating substrate 10 and buffer layer 14. In the semiconductor layer 143, an intrinsic or substantially intrinsic channel 143c is provided. On both sides of this channel 143c, a source 143s and a drain 143d are provided by ion doping.

On the semiconductor layer 143, the gate insulating film 12 and a gate electrode 141 made of refractory metal are laminated and formed in order.

Thereafter, the interlayer insulating film 15 is provided as in the case of the first TFT 210, a contact hole provided so as to correspond to the drain 143d is filled with metal, and the drive power line 153 connected to a drive power source is provided. Moreover, in a contact hole provided so as to correspond to the source 143s, a source electrode 158 is provided. Furthermore, the planarizing insulating film 17 is provided on the entire surface, and, in the planarizing insulating film 17 and the interlayer insulating film 15, a contact hole is formed at a position corresponding to the source electrode 158. Thereafter, a first electrode (anode) 161 of the organic EL element 167 is provided on the planarizing insulating film 17, the first electrode coming into contact with the source electrode 158 through the contact hole and being made of ITO (indium tin oxide).

An organic EL layer 165 is formed by laminating a hole transport layer 162, a light-emitting layer 163 and an electron transport layer 164 in this order on the anode 161. Furthermore, a second electrode (cathode) 166 made of magnesium-indium alloy is laminated and formed. This cathode 166 is provided on the entire surface of the substrate 10 forming an organic EL display device, or on the entire surface of the display unit 200, shown in FIG. 4B.

In the organic EL element 167, holes injected from the anode and electrons injected from the cathode recombine in the light-emitting layer. Accordingly, organic molecules forming the light-emitting layer are excited to generate excitons. Through radiation and quenching of the excitons, light is emitted from the light-emitting layer. This light is emitted from the transparent anode through the transparent insulating substrate to the outside.

Since a specific structure of the TFT to be the optical sensor 100 is also the same as that shown in FIG. 1A, detailed description thereof will be omitted. Here, the buffer layer 14, a semiconductor layer 13, the insulating film 12, a gate electrode 11, the interlayer insulating film 15 and the planarizing insulating film 17 in the optical sensor 100 are made of the same materials manufactured in the same steps as those of the buffer layer 14, the semiconductor layers 113 and 143, the gate insulating film 12, the gate electrodes 111 and 141, the interlayer insulating film 15 and the planarizing insulating film 17 in the two TFTs 210 and 220 included in the display unit 200. Specifically, the optical sensor 100 can be simultaneously formed on the same substrate 10 in the steps of manufacturing the display unit 200, and can be realized by use of the same constituent components as those of the display unit 200. Thus, it is possible to significantly contribute to simplification of the manufacturing process and reduction in the number of parts.

Moreover, the semiconductor layer 13 of the optical sensor 100 has the same film thickness as that of the TFT of the display unit 200, and the gate width W is increased only by changing patterns. In this event, it is preferable that a ratio of the gate width W to the gate length L of the optical sensor 100 (the gate width W/the gate length L) is set to be larger than the gate width W/the gate length L of the first TFT 210 or the second TFT 220 in the pixel. Further, it is preferable that the ratio is set to be larger than the gate width W/the gate length L of the first and second TFTs 210 and 210 in the pixel. Thus, a high-performance and high-efficiency display can be obtained. Note that, although an unillustrated light shielding film is provided in the display unit 200, it is preferable that the film is not be provided on the light pass of optical sensor 100. Thus, it is possible to allow more ambient light to enter.

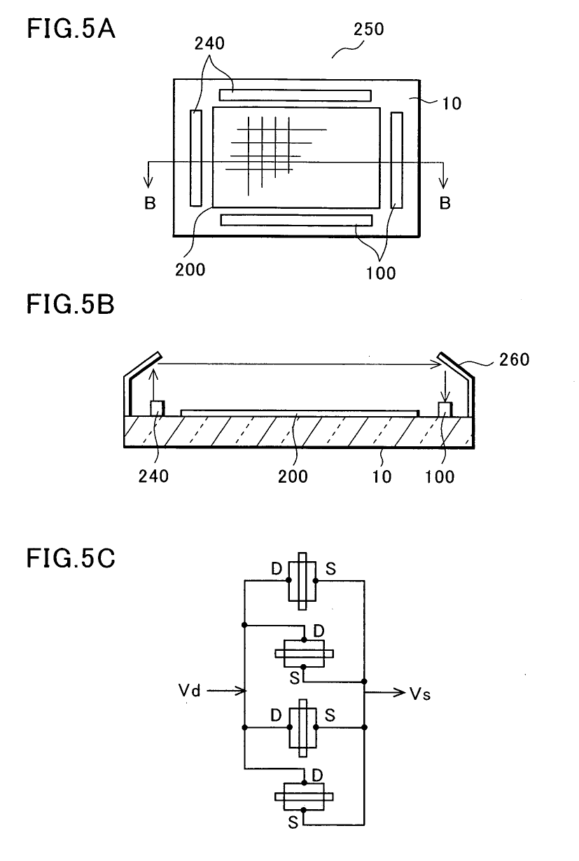

Furthermore, with reference to FIGS. 5A to 5C, a third embodiment will be described. This embodiment is also a display including an optical sensor on the same substrate, and is a so-called touch panel 250 which obtains input coordinates by allowing a finger or a pen to come into contact with a display unit.

FIG. 5A is a plan view of the touch panel 250, and FIG. 5B is a cross-sectional view taken along the line B-B in FIG. 5A. As shown in FIGS. 5A and 5B, light-emitting elements 240 and optical sensors 100 are arranged around a display unit 200. Since the display unit 200 is the same as that of the second embodiment effectively, description thereof will be omitted. But the display unit 200 has the pixels in which the order of laminating an organic EL element 167 is reversed. The light-emitting elements 240 have the same top emission type structure as that of the organic EL element 167 of the pixels included in the display unit 200. A plurality of light-emitting elements 240 are provided at regular intervals along two sides around the display unit 200.

Moreover, the optical sensors 100 are arranged along the other two sides of the display unit 200 at regular intervals so as to make pairs with the light-emitting elements 240, and have the same structure as that of the TFT shown in FIG. 1A. Furthermore, since the light-emitting elements 240 emit light upward from the substrate 10, a reflector 260 such as a mirror is provided on the same substrate 10 so that the light of the light-emitting elements 240 passes over the display unit 200 and reaches the optical sensors 100.

An example of a method for detecting input coordinates will be described. Among the light-emitting elements 240, those arranged on one side first sequentially emit light one by one. Next, the light-emitting elements 240 arranged on the other side sequentially emit light one by one. This emitted light is constantly received by the optical sensors 100 unless there is something above the display unit 200. When a finger or an input pen touches a predetermined position on the display unit 200, emission from specific light-emitting elements 240 is shut out, and the emitted light is no longer received by specific optical sensors 100. Based on this emission timing of the light-emitting elements 240 and output from the optical sensors 100, regions where emissions are shut out are sensed two-dimensionally, and the input coordinates are detected.

In this case, a plurality of the optical sensors 100 are also arranged along two sides of the display unit 200. However, one optical sensor 100 is divided and connected in parallel to obtain a total gate width W of 100 μm. In this case, for example, the gate width W is about 10 times long as the gate length L, and a shape of one TFT becomes approximately rectangular. Thus, as shown in FIG. 5C, the TFTs may be rotated 90 degrees and arranged so as to alternate their directions one after the other. Thus, the gate electrodes are arranged to allow the gate length directions to be at right angles to each other. By providing a plurality of TFTs, redundancy as the optical sensor 100, and averaging of light received can be achieved.

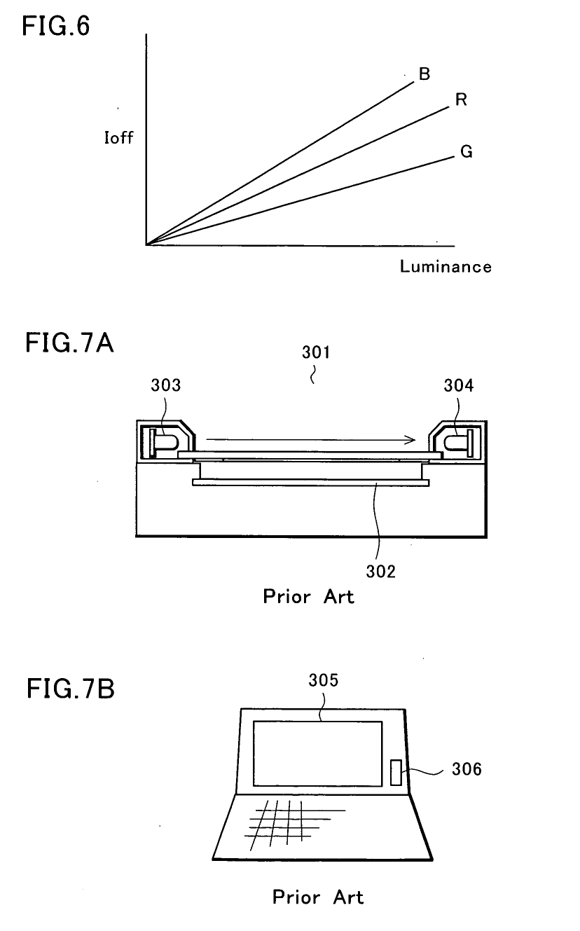

Note that, when light from the light-emitting elements is received as described above, the light-emitting elements 240 may emit blue light. As is clear from FIG. 6 showing a relationship between brightness of a light source and Ioff, the line indicating blue light in FIG. 6 has a steep slope. Thus, large Ioff can be obtained even with a small amount of light.

As described above, the display of this embodiment has the optical sensors with good sensitivity provided on the same substrate as that of the flat panel display. Therefore, without being limited to the structures shown in the second and third embodiments, any structure is applicable as long as the structure is one in which the display unit and the optical sensors are formed on the same substrate. Thus, the display unit is not limited to one using the organic EL elements, but may be one using inorganic EL elements, liquid crystal display elements, plasma display elements, or the like.

The examples explained above are based on a display device of bottom emission type. However, the optical sensors of the embodiments are also applicable to a display device of top emission type in which light is outputted in a direction opposite from the insulating substrate.

1. An optical sensor comprising:
a substrate;
a semiconductor layer disposed over the substrate and comprising a source, a drain and a channel disposed between the source and the drain, the semiconductor layer being configured to generate photocurrents in response to light incident thereto;
a gate electrode disposed over the substrate, a gate width of the gate electrode being at least 10 times as large as a gate length of the gate electrode; and
a gate insulating film disposed between the semiconductor layer and the gate electrode.

2. The optical sensor of claim 1, wherein the gate width is from 5 μm to 10000 μm.

3. The optical sensor of claim 1, wherein the photocurrents are generated in a junction region induced in the semiconductor layer between the source and the channel or between the drain and the channel.

4. The optical sensor of claim 1, further comprising a low concentration impurity region formed in the semiconductor layer between the source and the channel or between the drain and the channel.

5. The optical sensor of claim 4, wherein the low concentration impurity region is disposed on a side of the semiconductor layer from which the photocurrents are outputted.

6. The optical sensor of claim 1, wherein the gate electrode, the source and the gate are configured to receive respective voltages at a predetermined time interval.

7. A display device comprising:
a substrate;
a display unit disposed on the substrate and comprising a plurality of pixels each comprising a thin film transistor; and
an optical sensor comprising a semiconductor layer disposed over the substrate, a gate electrode disposed over the substrate and a gate insulating film disposed between the semiconductor layer and the gate electrode, a gate width of the gate electrode being at least 10 times as large as a gate length of the gate electrode, and the semiconductor layer comprising a source, a drain and a channel disposed between the source and the drain.

8. The display device of claim 7, wherein the optical sensor is configured to receive ambient light so as to control brightness of the display unit.

9. The display device of claim 7, further comprising a light emitting element so as to send light to the optical sensor.

10. The display device of claim 7, further comprising additional optical sensors, wherein the optical sensor and the additional optical sensors are connected in parallel, and a sum of gate width of the optical sensor and the additional optical sensors is from 5 μm to 10000 μm.

11. The display device of claim 7, further comprising a low concentration impurity region formed in the semiconductor layer between the source and the channel or between the drain and the channel.

12. The display device of claim 7, wherein the thin film transistor comprises a gate insulating film, a gate electrode and a semiconductor layer that are made of same materials as respective elements of the optical sensor.

13. The display device of claim 7, wherein a gate-width-over-gate-length ratio of the optical sensor is larger than the ratio of the thin film transistor.

14. The display device of claim 7, further comprising additional optical sensors, wherein the optical sensor and the additional optical sensors are arranged around the display unit.

15. A display device comprising:
a substrate;
a display unit disposed on the substrate and comprising a plurality of pixels each comprising a thin film transistor and an electroluminescent element; and
an optical sensor comprising a semiconductor layer disposed over the substrate, a gate electrode disposed over the substrate and a gate insulating film disposed between the semiconductor layer and the gate electrode, a gate width of the gate electrode being at least 10 times as large as a gate length of the gate electrode, and the semiconductor layer comprising a source, a drain and a channel disposed between the source and the drain.

16. The display device of claim 15, wherein the electroluminescent element comprises a first electrode, a second electrode and a light-emitting layer disposed between the first and second electrodes.

17. The display device of claim 15, wherein the optical sensor is configured to receive ambient light so as to control brightness of the display unit.

18. The display device of claim 15, further comprising a light emitting element so as to send light to the optical sensor.

19. The display device of claim 15, further comprising additional optical sensors, wherein the optical sensor and the additional optical sensors are connected in parallel, and a sum of gate width of the optical sensor and the additional optical sensors is from 5 μm to 10000 μm.

20. The display device of claim 15, further comprising a low concentration impurity region formed in the semiconductor layer between the source and the channel or between the drain and the channel.

21. The display device of claim 15, wherein the thin film transistor comprises a gate insulating film, a gate electrode and a semiconductor layer that are made of same materials as respective elements of the optical sensor.

22. The display device of claim 15, wherein a gate-width-over-gate-length ratio of the optical sensor is larger than the ratio of the thin film transistor.

23. The display device of claim 15, further comprising additional optical sensors, wherein the optical sensor and the additional optical sensors are arranged around the display unit.

24. A display device comprising:
a substrate;
a display unit disposed on the substrate and comprising a plurality of pixels each comprising a thin film transistor; and
an optical sensor comprising a semiconductor layer disposed over the substrate, a gate electrode disposed over the substrate and a gate insulating film disposed between the semiconductor layer and the gate electrode, the semiconductor layer comprising a source, a drain and a channel disposed between the source and the drain,
wherein a gate width of the gate electrode is larger than a gate length of the gate electrode, and photocurrent induced in the optical sensor is larger than 1×10⁻⁹A.

25. An optical sensor comprising:
a substrate; and
a first thin film transistor and a second thin film transistor that are connected in parallel and configured to generate photocurrents in response to light incident thereto, each of the first and second thin film transistor comprising a semiconductor layer disposed over the substrate, a gate electrode disposed over the substrate and a gate insulating film disposed between the semiconductor layer and the gate electrode,
wherein a direction of gate length of the first thin film transistor is different from a direction of gate length of the second thin film transistor.

26. The optical sensor of claim 25, wherein the direction of gate length of the first thin film transistor is perpendicular to the direction of gate length of the second thin film transistor.
